(19) United States
(12) Patent Application Publication
(10) Pub. No.: US 2024/0102142 A1
(43) Pub. Date: Mar. 28, 2024

(54) SPRAY COATING, SRAYING POWDER, SPRAYING POWDER MANUFACTURING METHOD AND SPRAY COATING MANUFACTURING METHOD

(71) Applicant: Shin-Etsu Chemical Co., Ltd., Tokyo (JP)

(72) Inventors: Noriaki Hamaya, Echizen-shi (JP); Ichiro Uehara, Echizen-shi (JP)

(73) Assignee: Shin-Etsu Chemical Co., Ltd., Tokyo (JP)

(21) Appl. No.: 18/517,251

(22) Filed: Nov. 22, 2023

Related U.S. Application Data
(62) Division of application No. 16/489,070, filed on Aug. 27, 2019, now abandoned.

(30) Foreign Application Priority Data
Mar. 1, 2017 (JP) 2017-038174

(51) Int. Cl. C23C 4/11; B32B 9/00; C01F 17/259; C01F 17/265; C04B 35/50; C04B 35/515; C09D 1/00; C09D 5/03; C23C 4/134

(52) U.S. Cl. CPC C23C 4/11; B32B 9/005; C01F 17/259; C01F 17/265; C04B 35/50; C04B 35/5156; C09D 1/00; C09D 5/03; C23C 4/134; C04B 2237/34; C04B 2237/36

(57) ABSTRACT

A spray coating containing a rare earth fluoride and/or a rare earth acid fluoride contains carbon at 0.01-2% by mass or titanium or molybdenum at 1-1000 ppm. When an acid fluoride is not contained, the spray coating is gray to black in which, in terms of the L*a*b* chromaticity, L* is 25-64, a* is −3.0 to +5.0, and b* is −4.0 to +8.0. When an acid fluoride is contained, the spray coating is white or gray to black in which, in terms of the L*a*b* chromaticity, L* is equal to or greater than 25 and less than 91, a* is −3.0 to +5.0, and b* is −6.0 to +8.0. By forming this coating on a plasma resistant member, a partial color change is reduced, thus, a member that is capable of reliably realizing the original longevity is obtained.

### CROSS-REFERENCE TO RELATED APPLICATION

The present application is a divisional application of U.S. patent application Ser. No. 16/489,070, filed on Aug. 27, 2019, which is a national stage application filed under 35 USC 371 of International Application No. PCT/JP2018/007624, filed Feb. 28, 2018, and which is based upon and claims the benefit of priority from the prior Japanese Patent Application No. 2017-038174, filed on Mar. 1, 2017, the entire contents of which are incorporated herein by reference.

### TECHNICAL FIELD

This invention relates to a sprayed coating containing a rare earth fluoride or the rare earth fluoride and a rare earth oxyfluoride, a spraying powder for producing the sprayed coating, a method for preparing the spraying powder, and a method for preparing the sprayed coating.

### BACKGROUND ART

Rare earth fluorides are relatively stable at high temperature. So, recently, development of members in which are formed a rare earth fluoride sprayed coating is made for the purposes of reducing initial particles and prolonging their lifetime by utilizing a rare earth fluoride for use in plasma-resistant members. Such members are used, for example, in a plasma etching system using halogen gas.

In general, yttrium fluoride representative of rare earth fluorides displays white color. Whereas, after spray coated members are used in a plasma etching system using halogen gas, decomposed resist residues deposit on the members to generate brown-colored portions. Since there arises a phenomenon that the member surface is partially discolored from white to black under the influence of plasma etching (e.g., defective holes by color centers), the discolored areas must be concentratedly cleaned. Accordingly, the lifetime of the sprayed coating shortened by this cleaning, although the sprayed coatings, intrinsically have a long lifetime owing to plasma resistance. The patent documents 1 to 6 are listed as prior art documents.

### PRIOR ART DOCUMENTS

### Patent Documents

Patent Document 1: JP-A 2004-100039
Patent Document 2: JP-A 2012-238894
Patent Document 3: JP-B 3894313
Patent Document 4: JP-A 2014-010638
Patent Document 5: JP-B 5396672
Patent Document 6: JP-A 2016-079258

### SUMMARY OF THE INVENTION

### Problems to be Solved by the Invention

The present invention has been done in view of the above circumstances. An object of the invention is to provide a sprayed coating experiencing little local discoloration after use, a spraying powder for producing the sprayed coating, and a method for preparing the sprayed coating or the spraying powder.

### Means for Solving the Problems

The present inventors have earnestly studied in order to attain the above object, and the present invention has been accomplished. The above-mentioned problem resides in that rare earth fluorides or rare earth fluorides containing oxyfluorides basically appear white color. From this standpoint, it may be contemplated to add another element to a rare earth fluoride to color it gray or black. Since plasma-resistant members are mainly used in the semiconductor fabrication process, it is necessary from the aspect of preventing contamination to reduce the amount of the additive element. Thus, it has been desired to form a sprayed coating of a rare earth fluoride or a rare earth fluoride containing oxyfluoride having a white color or gray to black color of the prescribed chromaticity with using a minor amount of additive element. Consequently, the present inventors have continuously studied in view of the desire, and found that beneficial effects are obtained when carbon, or titanium or molybdenum is added to the rare earth fluoride, particularly, when carbon is added in an amount of 0.01 to 2% by weight or when titanium or molybdenum is added in an amount of 1 to 1,000 ppm. Further examining sprayed coatings in terms of L*a*b* chromaticity, the inventors have found that a sprayed coating having a white color or gray to black color which can accomplish the object of the present invention is obtainable using a spraying powder of rare earth fluoride or rare earth fluoride containing oxyfluoride that displays a white color or gray to black color having an L* value of at least 25 and less than 91, or 25 to 64 in some cases, an a* value of −3.0 to +5.0, and a b* value of −6.0 to +8.0 when expressed by the L*a*b* colorimetric system. The present invention has been accomplished in view of these findings.

Accordingly, the present invention provides, as a first invention, a sprayed coating, a spraying powder and a method for preparing a spraying powder, as defined below.

[1] A sprayed coating composed of the following (1) and/or (2), or the mixture of the following (1) and/or (2) and one or two or more selected from the following (3) to (5):
(1) a fluoride of at least one rare earth element selected from rare earth elements comprising yttrium that belong in Group 3A;
(2) an oxyfluoride of the rare earth element;
(3) an oxide of the rare earth element;
(4) a composite oxide of the rare earth element and at least one or two or more metals selected from Al, Si, Zr and In; and
(5) a composite fluoride of the rare earth element and at least one or two or more metals selected from Al, Si, Zr and In,
wherein, the sprayed coating contains 0.004 to 2% by weight of carbon or 1 to 1,000 ppm of titanium or molybdenum, and
in case where the sprayed coating does not contain the oxyfluoride (2), the sprayed coating displays a gray to black color having an L* value of 25 to 64, an a* value of −3.0 to +5.0, and a b* value of −6.0 to +8.0, expressed by L*a*b* colorimetric system, or
in case where the sprayed coating contains the oxyfluoride (2), the sprayed coating displays a white color or gray to black color having an L* value of at least 25 and less than 91, an a* value of −3.0 to +5.0, and a b* value of −6.0 to +8.0, expressed by L*a*b* colorimetric system.

[2] The sprayed coating of [1] wherein the rare earth element is at least one selected from Y, Gd, Yb, and La.

[3] The sprayed coating of [1] or [2], having an oxygen content of 0.01 to 13.5% by weight.

[4] The sprayed coating of any one of [1] to [3], having a carbon content of 0.004 to 0.15% by weight.

[5] A spraying powder composed of the following (1) and/or (2), or the mixture of the following (1) and/or (2) and one or two or more selected from the following (3) to (6):
(1) a fluoride of at least one rare earth element selected from rare earth elements comprising yttrium that belong in Group 3A;
(2) an oxyfluoride of the rare earth element;
(3) an oxide of the rare earth element;
(4) a composite oxide of the rare earth element and at least one or two or more metals selected from Al, Si, Zr and In;
(5) a composite fluoride of the rare earth element and at least one or two or more metals selected from Al, Si, Zr and In; and
(6) an oxide of at least one or two or more metals selected from Al, Si, Zr and In,
wherein, the spraying powder contains 0.004 to 2% by weight of carbon or 1 to 1,000 ppm of titanium or molybdenum, and
the spraying powder displays a white color or gray to black color having an L* value of at least 25 and less than 91, an a* value of −3.0 to +5.0, and a b* value of −6.0 to +8.0, expressed by L*a*b* colorimetric system.

[6] The spraying powder of [5] wherein the rare earth element is at least one selected from Y, Gd, Yb, and La.

[7] The spraying powder of [5] or [6], having an oxygen content of 0.01 to 13.5% by weight.

[8] The spraying powder of any one of [5] to [7], being a fired spraying powder and having a carbon content of 0.004 to 0.15% by weight.

[9] The spraying powder of any one of [5] to [7], being an unfired spraying powder and having a carbon content of 0.004 to 1.5% by weight.

A method for preparing a spraying powder of any one of [5] to [8], the method comprising the steps of:
drying a slurry comprising a powder displaying a white color and composed of the following (1) and/or (2), or the mixture of the following (1) and/or (2) and one or two or more selected from the following (3) to (6):
(1) a fluoride of at least one rare earth element selected from rare earth elements comprising yttrium that belong in Group 3A;
(2) an oxyfluoride of the rare earth element;
(3) an oxide of the rare earth element;
(4) a composite oxide of the rare earth element and at least one or two or more metals selected from Al, Si, Zr and In;
(5) a composite fluoride of the rare earth element and at least one or two or more metals selected from Al, Si, Zr and In; and
(6) an oxide of at least one or two or more metals selected from Al, Si, Zr and In, and an appropriate amount of a carbon source to produce a spraying powder having a carbon concentration of 0.004 to 2% by weight,
roasting and firing the resulting dried material, and
thereby obtaining a spraying powder displaying a white color or gray to black color having an L* value of at least 25 and less than 91, an a* value of −3.0 to +5.0, and a b* value of −6.0 to +8.0, expressed by L*a*b* colorimetric system.

[11] The method for preparing a spraying powder of [10] wherein the roasting is subjected at 500 to 800° C. in nitrogen gas, and then the firing is subjected to the roasted powder at 800 to 1,000° C. in vacuum or an inert gas atmosphere.

[12] The method for preparing a spraying powder of [10] or [11] wherein the powder displaying a white color and composed of said (1) and/or (2), or the mixture of said (1) and/or (2) and one or two or more selected from said (3) to (6) has an oxygen content of 0.01 to 13.5% by weight.

[13] The method for preparing a spraying powder of any one of [10] to [12] wherein the carbon source is used in an appropriate amount to produce a spraying powder having a carbon concentration of 0.004 to 0.15% by weight.

[14] A method for preparing a spraying powder of any one of [5] to [8], the method comprising the steps of:
drying with granulating a slurry comprising a powder displaying a white color and composed of the following (1) and/or (2), or the mixture of the following (1) and/or (2) and one or two or more selected from the following (3) to (6):
(1) a fluoride of at least one rare earth element selected from rare earth elements comprising yttrium that belong in Group 3A;
(2) an oxyfluoride of the rare earth element;
(3) an oxide of the rare earth element;
(4) a composite oxide of the rare earth element and at least one or two or more metals selected from Al, Si, Zr and In;
(5) a composite fluoride of the rare earth element and at least one or two or more metals selected from Al, Si, Zr and In; and
(6) an oxide of at least one or two or more metals selected from Al, Si, Zr and In, polyvinyl alcohol, and an appropriate amount of a water-soluble salt of titanium or molybdenum to produce a spraying powder having a titanium or molybdenum concentration of 1 to 1,000 ppm,
firing the resulting powder, and
thereby obtaining a spraying powder displaying a white color or gray to black color having an L* value of at least 25 and less than 91, an a* value of −3.0 to +5.0, and a b* value of −6.0 to +8.0, expressed by L*a*b* colorimetric system.

[15] The method for preparing a spraying powder of [14] wherein the firing is subjected to the dried/granulated powder at 800 to 1,000° C. in vacuum or an inert gas atmosphere.

[16] The method for preparing a spraying powder of [14] or [15] wherein the powder displaying a white color and composed of said (1) and/or (2), or the mixture of said (1) and/or (2) and one or two or more selected from said (3) to (6) has an oxygen content of 0.01 to 13.5% by weight.

Continuing further investigations, the inventors have found that even in the absence of carbon, titanium and molybdenum, by treating a rare earth fluoride coating with plasma light and reactive gas, the coating surface is converted to a gray to black color due to color centers created, and found that, when a spray coated member in which the surface of a sprayed coating has been colored to gray to black color in advance by plasma exposure treatment is used in a plasma etching system, the coating experiences no discoloration after the use. Consequently, that the above-described object of the present invention can be accomplished by these findings.

Accordingly, the present invention provides, as a second invention, a sprayed coating and a method for preparing a sprayed coating, as defined below.

[17] A sprayed coating composed of the following (1) and/or (2), or the mixture of the following (1) and/or (2) and one or two or more selected from the following (3) to (5):
(1) a fluoride of at least one rare earth element selected from rare earth elements comprising yttrium that belong in Group 3A;
(2) an oxyfluoride of the rare earth element;
(3) an oxide of the rare earth element;
(4) a composite oxide of the rare earth element and at least one or two or more metals selected from Al, Si, Zr and In; and
(5) a composite fluoride of the rare earth element and at least one or two or more metals selected from Al, Si, Zr and In,
wherein the sprayed coating comprises at its surface a gray to black colored layer displaying a gray to black color having an L* value of 25 to 64, an a* value of −3.0 to +5.0, and a b* value of −6.0 to +8.0, expressed by L*a*b* colorimetric system.

[18] The sprayed coating of [17] wherein the gray to black colored layer has a depth of up to 2 μm from the surface of the sprayed coating.

[19] The sprayed coating of [17] or [18], having an oxygen content of 0.01 to 13.5% by weight.

[20] A method for preparing a sprayed coating of any one of [17] to [19], the method comprising the steps of:
thermally spraying a powder to a surface of a substrate, the powder displaying a white color and composed of the following (1) and/or (2), or the mixture of the following (1) and/or (2) and one or two or more selected from the following (3) to (6):
(1) a fluoride of at least one rare earth element selected from rare earth elements comprising yttrium that belong in Group 3A;
(2) an oxyfluoride of the rare earth element;
(3) an oxide of the rare earth element;
(4) a composite oxide of the rare earth element and at least one or two or more metals selected from Al, Si, Zr and In;
(5) a composite fluoride of the rare earth element and at least one or two or more metals selected from Al, Si, Zr and In; and
(6) an oxide of at least one or two or more metals selected from Al, Si, Zr and In,
forming a sprayed coating displaying a white color having an L* value of at least 81, an a* value of −3.0 to +3.0, and a b* value of −3.0 to +3.0, expressed by L*a*b* colorimetric system, and
effecting plasma exposure treatment on the resulting sprayed coating to form a gray to black colored layer at its surface, the gray to black colored layer displaying a gray to black color having an L* value of 25 to 64, an a* value of −3.0 to +5.0, and a b* value of −6.0 to +8.0, expressed by L*a*b* colorimetric system.

[21] The method for preparing a sprayed coating of wherein the gray to black colored layer is formed with a depth of up to 2 μm from the surface of the sprayed coating.

[22] The method for preparing a sprayed coating of or wherein the powder displaying white color and composed of said (1) and/or (2), or the mixture of said (1) and/or (2) and one or two or more selected from said (3) to (6) has an oxygen content of 0.01 to 13.5% by weight.

### ADVANTAGEOUS EFFECTS OF THE INVENTION

According to the invention, a rare earth fluoride sprayed coating of a rare earth fluoride or a rare earth fluoride containing oxyfluoride displaying a white color or gray to black color of the prescribed chromaticity can be deposited by atmospheric plasma spraying, which leads to a cost reduction. When a member having a sprayed coating obtained from thermal spraying of the rare earth fluoride that displays a white color or gray to black color of the prescribed chromaticity is used as a plasma-resistant member in halogen gas, the member experiences no local discoloration. When the member is taken out and cleaned, no excessive partial cleaning is necessary. The member surely maintains its intrinsic long lifetime.

### BRIEF DESCRIPTION OF DRAWINGS

FIG. 1 schematically illustrates a measuring method for the thickness of a black color layer in a sprayed coating.

FIG. 2 is a graph showing relationship between carbon content and hardness of the sprayed coating in Experimental Examples.

### EMBODIMENT FOR CARRYING OUT THE INVENTION

Now the invention is described in detail.

In the invention as a first embodiment, a sprayed coating is composed of the following (1) and/or (2), or the mixture of the following (1) and/or (2) and one or two or more selected from the following (3) to (5):
(1) a fluoride of at least one rare earth element selected from rare earth elements comprising yttrium that belong in Group 3A;
(2) an oxyfluoride of the rare earth element;
(3) an oxide of the rare earth element;
(4) a composite oxide of the rare earth element and at least one or two or more metals selected from Al, Si, Zr and In; and
(5) a composite fluoride of the rare earth element and at least one or two or more metals selected from Al, Si, Zr and In.

A spraying powder of the invention is composed of the following (1) and/or (2), or the mixture of the following (1) and/or (2) and one or two or more selected from the following (3) to (6):
(1) a fluoride of at least one rare earth element selected from rare earth elements comprising yttrium that belong in Group 3A;
(2) an oxyfluoride of the rare earth element;
(3) an oxide of the rare earth element;
(4) a composite oxide of the rare earth element and at least one or two or more metals selected from Al, Si, Zr and In;
(5) a composite fluoride of the rare earth element and at least one or two or more metals selected from Al, Si, Zr and In; and
(6) an oxide of at least one or two or more metals selected from Al, Si, Zr and In.

As described above, at least one rare earth element selected from rare earth elements comprising yttrium that belong in Group 3A is used as a rare earth element. Typically, the rare earth element is at least one or two or more heavy rare earth element selected from Y, Gd, Yb, and La. The yttrium oxyfluoride having any crystal structure may be used such as Y₅O₄F₇, Y₆O₅F₈, YOF and so on, in case of oxyfluorides of the rare earth element (2).

Particles of the spraying powder of the present invention preferably has an average particle size of 1 to 100 μm. If the particle size is less than 1 μm, such small particles may evaporate and scatter away in plasma flame during thermal spraying, leading to a material loss. If the particle size is more than 100 μm, such large particles may not be completely melted in plasma flame during thermal spraying, and some particles left unmolten may cause a reduction of bond strength. Notably, the average particle size is a D₅₀ value in particle size distribution measured by the laser diffraction method.

The sprayed coating or spraying powder is prepared by incorporating a component capable of imparting a gray to black color into a powder normally displaying a white color and being a rare earth fluoride (e.g., a rare earth fluoride powder having an L* value of a least 91, an a* value of −3.0 to +3.0, and a b* value of −3.0 to +3.0) or a rare earth fluoride containing oxyfluoride so that the sprayed coating or spraying powder may display an L* value of less than 91, an a* value of −3.0 to +5.0, and a b* value of −6.0 to +8.0 when expressed by L*a*b* colorimetric system. However, the L* value of a sprayed coating not containing the oxyfluoride of the rare earth element (2) is 25 to 64. The component capable of imparting a gray to black color is typically carbon, titanium or molybdenum. Carbon is incorporated in the coating or powder in an amount of preferably 0.004 to 2% by weight, more preferably 0.05 to 1.8% by weight. Titanium or molybdenum is incorporated in the coating or powder in an amount of preferably 1 to 1,000 ppm, more preferably 1 to 800 ppm. The sprayed coating or spraying powder has an oxygen content of preferably 0.01 to 13.5% by weight, more preferably 0.05 to 8% by weight although the oxygen content is not limited thereto.

According to the finding of the inventors, the carbon content may affect to a hardness of the coating and large amount of carbon may result to reduction of the hardness of the coating. Therefore, the carbon content is preferably up to 0.15% by weight, more preferably up to 0.1% by weight, in case where high hardness is required to the coating.

In addition, the lower limit of the carbon content range may be 0.004% by weight described above, and is preferably 0.01% by weight, more preferably 0.02% by weight. In this way, a coating having a hardness of at least 300 HV, particularly at least 400 HV may be obtained. To obtain a coating having such a high hardness, a spraying powder that is fired may have a carbon content of 0.004 to 0.15% by weight, or a spraying powder that is not fired may have a carbon content of 0.004 to 1.5% by weight. A sprayed coating having a carbon content of up to 0.15% by weight and the good hardness described above is obtained by thermal spraying with using the spraying powder like this.

Although the means for incorporating carbon is not particularly limited, one exemplary procedure includes the steps of preparing a slurry by using a solution containing, for example, a powder displaying white color and composed of the above-described (1) and/or (2), or the mixture of the above-described (1) and/or (2) and one or two or more selected from the above-described (3) to (6), and a carbon source, mixing the slurry for 5 to 60 minutes, drying, granulating and firing. The carbon source used herein may be carbon, aliphatic hydrocarbons and aromatic hydrocarbons, which may be mixed or dissolved in water or organic solvents, if desired. For example, phenol diluted with alcohol, or water-soluble organic materials such as acryl type binder, carboxymethyl cellulose (CMC), polyvinyl alcohol (PVA) and sucrose may be used. The carbon source is not limited thereto as long as carbon is obtained by firing the source. Carbon may be added by any direct means such as mixing, dipping, coating or spraying. Once the carbon source and the powder are mixed and dried, the mixture is preferably fired at 500 to 1,000° C. in nitrogen gas. The firing may be followed by sieving, yielding a spraying powder displaying a white color or gray to black color of the prescribed chromaticity. In addition, after the step of mixing the carbon source and the powder, drying and granulating, the mixed/dried powder may be directly used for a spraying powder without firing. Further, in case that a fine spraying powder (particle size of 1 to 10 μm) that is used in a slurry for SPS (suspension plasma spraying), the steps of drying and granulating are not necessary.

When the spraying powder is prepared in this way, it is important to control the concentration of the carbon source (e.g., phenol, acryl type binder, CMC, PVA, sucrose and so on) so that the resulting spraying powder may have a carbon concentration of 0.04 to 2% by weight. If the carbon content is less than 0.04% by weight, the desired colored coating is not obtained, with the possibility of powder strength being weakened or powder properties varying upon high-temperature firing or thermal spraying. If the carbon content exceeds 2% by weight, carbon in such high concentration may become a surplus, leading to contamination or reduction of hardness of the sprayed coating in many cases. In addition, as described above, to form a coating having such a high hardness such as at least 300 HV, particularly at least 400 HV, it is preferably to control an additive concentration of carbon source so that a spraying powder that is fired has 0.004 to 0.15% by weight, preferably 0.01 to 0.1% by weight, or a spraying powder that is not fired has 0.004 to 1.5% by weight.

Although the means for incorporating titanium or molybdenum is not particularly limited, one exemplary procedure includes the steps of mixing a powder, for example, a powder displaying white color and composed of the above-described (1) and/or (2), or the mixture of the above-described (1) and/or (2) and one or two or more selected from the above-described (3) to (6), polyvinyl alcohol (PVA), water, and a water-soluble salt of titanium or molybdenum (e.g., titanium chloride, titanium ammonium, molybdenum chloride, molybdenum ammonium and so on) to form a slurry, granulating and drying the slurry through a spray dryer. The resulting powder is fired at 800 to 1,000° C. in vacuum or inert gas atmosphere, yielding a spraying powder of a gray to black color. In this case, the spraying powder has a titanium or molybdenum content of 1 to 1,000 ppm. If the titanium or molybdenum content is less than 1 ppm, a coating of the desired color is not obtained. If the titanium or molybdenum content exceeds 1,000 ppm, it may become a cause of contamination particularly when a spray coated member is used in a semiconductor fabrication system.

The sprayed coating may be deposited or formed by thermally spraying the spraying powder of the present invention to a substrate, for example, a member for use in a plasma etching system. The substrate used herein is not particularly limited, and may be selected from substrates of metals, alloys, ceramics such as metal nitrides, metal carbides, metal oxides (e.g., alumina, aluminum nitride, silicon nitride, and silicon carbide) and glass such as quartz glass, and the metal being based on Al, Fe, Si, Cr, Zn, Zr or Ni.

The thickness of the sprayed coating may be set as appropriate depending on a particular application and is not particularly limited. Particularly when the sprayed coating is formed as a corrosion resistant coating on a member used in a plasma etching system for the purpose of imparting corrosion resistance to the member, the coating thickness is preferably 50 to 500 μm, more preferably 150 to 300 μm. If the coating thickness is less than 50 μm, the spray coated member must be replaced just after a little corrosion. If the coating thickness is more than 500 μm, such an over-thick coating is likely to peel apart.

The sprayed coating may be formed by thermally spraying the spraying powder of the present invention onto the surface of a substrate by any appropriate thermal spray techniques such as plasma spraying, low pressure plasma spraying, and SPS. The plasma gas used herein is not particularly limited and may be selected from nitrogen/hydrogen, argon/hydrogen, argon/helium, argon/nitrogen, argon/hydrogen/nitrogen and so on. The spraying conditions are not particularly limited and may be set as appropriate depending on the type of substrate, each of the materials contained in spraying powder such as a rare earth fluoride, the application of the spray coated member, and the like.

The sprayed coating thus obtained, as described above, in case where the sprayed coating does not contain the oxyfluoride (2) of the rare earth element, the sprayed coating displays a gray to black color having an L* value of 25 to 64, an a* value of −3.0 to +5.0, and a b* value of −6.0 to +8.0 when expressed by L*a*b* colorimetric system. In case where the sprayed coating contains the oxyfluoride (2) of the rare earth element, the sprayed coating displays a white color or gray to black color having an L* value of at least and less than 91, preferably 25 to 85, more preferably 25 to 80, an a* value of −3.0 to +5.0, and a b* value of −6.0 to +8.0 when expressed by L*a*b* colorimetric system. The sprayed coating of a white color or gray to black color as definitely prescribed by the L*a*b* colorimetric system eliminates a need for excessive partial cleaning of the spray coated member upon deinstallation and cleaning, and allows the spray coated member to produce intrinsic long lifetime. It is noted that the L*a*b* chromaticity is measured according to JIS Z8729, for example, by Chroma Meter CR-200 (Konica Minolta Inc.) in the present invention.

In the sprayed coating of the present invention, when a spraying powder consisting of only the fluoride of rare earth element (1), for example, a spraying powder consisting of only YF₃ is thermal sprayed, a sprayed coating having a gray to black color and a crystal structure of only YF₃ is obtained. On the other hand, when a spraying powder in which the fluoride of rare earth element (1) is mixed with the oxyfluoride of rare earth element (2) and/or the oxide of rare earth element (3) is thermal sprayed, for example, a spraying powder in which YF₃ is mixed with Y oxyfluoride (Y₅O₄F₇ or Y₆O₅F₈) and/or an oxide (Y₂O₃) is thermal sprayed, a sprayed coating having a white color or gray to black color of the prescribed chromaticity and including multiple phases of YF₃ crystal phase along with other Y oxyfluoride crystal phase such as YF₃+Y₅O₄F₇ and YF₃+Y₆O₅F₈ is obtained. Further, when a spraying powder in which the fluoride of rare earth element (1) is mixed with the metal oxide (6) is thermal sprayed, for example, a spraying powder in which YF₃ is mixed with Al-containing oxide is thermal sprayed, a sprayed coating including multiple phases of a fluoride and/or an oxyfluoride, and YAG such as YOF+Y₃Al₅O₁₂+Y₇O₆F₉, YF₃+Y₅O₄F₇+Y₃Al₅O₁₂ and Y₆O₅F₈+Y₃Al₅O₁₂ is obtained. These crystal structures of the sprayed coating can be measured by X-ray diffraction method.

An oxygen content of the sprayed coating or spraying powder is determined by amounts of oxygen in an oxide of a rare earth element, an oxyfluoride (e.g., Y₂O₃ and Y₅O₄F₇) and so on contained in raw materials

In case where the sprayed coating contains smaller amount of oxygen, the sprayed coating has YF₃+Y₅O₄F₇ crystal structure, and the crystal structure shifts to YF₃+YOF crystal structure with increasing its oxygen amount. In case where the sprayed coating contains further large amount of oxygen, Y₂O₃ crystal structure may be measured along with YF₃+YOF crystal structure in some cases. These structures are identified through an XRD chart. In the present invention, as described above, whereas the sprayed coating or spraying powder has an oxygen content of preferably 0.01 to 13.5% by weight, more preferably 0.05 to 8% by weight, when the oxygen content is up to 6% by weight, particularly 2 to 4% by weight, the sprayed coating has a hardness of at least 300 HV, a sprayed coating superior in ability of plasma resistance is thus provided, and displaying a white color or gray to black color having an L* value of at least 25 and less than 91, an a* value of −3.0 to +5.0, and a b* value of −6.0 to +8.0.

In the sprayed coating and spraying powder of the present invention, when the sprayed coating or spraying powder does not contain the oxyfluoride of rare earth element (2), as described above, the upper limit of a L* value should be 64. The sprayed coating can achieve long lifetime by cleaning, when the L* value is controlled lower. Notably, the color of spraying powder or sprayed coating can be arbitrarily controlled within less than the L* value 91 corresponding to white color because a chromaticity L* is controllable with carbon content. In this way, the present invention can provide the spraying powder and sprayed coating having a white color or gray to black color of prescribed chromaticity.

In the invention as a second embodiment, a sprayed coating is formed initially by thermally spraying a powder displaying white color and composed of the following (1) and/or (2), or the mixture of the following (1) and/or (2) and one or two or more selected from the following (3) to (6):
(1) a fluoride of at least one rare earth element selected from rare earth elements comprising yttrium that belong in Group 3A;
(2) an oxyfluoride of the rare earth element;
(3) an oxide of the rare earth element;
(4) a composite oxide of the rare earth element and at least one or two or more metals selected from Al, Si, Zr and In;
(5) a composite fluoride of the rare earth element and at least one or two or more metals selected from Al, Si, Zr and In; and
(6) an oxide of at least one or two or more metals selected from Al, Si, Zr and In, to a surface of a substrate, and obtaining a sprayed coating displaying a white color having an L* value of at least 91, an a* value of −3.0 to +3.0, and a b* value of −3.0 to +3.0 when expressed by L*a*b* colorimetric system.

Next, plasma exposure treatment is effected on the sprayed coating to form a gray to black colored layer at its surface, the layer displaying a gray to black color having an L* value of 25 to 64, an a* value of −3.0 to +5.0, and a b* value of −6.0 to +8.0 when expressed by the L*a*b* colorimetric system. The gray to black colored layer preferably has a depth or thickness of up to 2 μm, especially about 1 μm from the surface of the sprayed coating although the depth is not particularly limited.

In this way, a sprayed coating is characterized in that the sprayed coating is composed of the following (1) and/or (2), or the mixture of the following (1) and/or (2) and one or two or more selected from the following (3) to (5):
(1) a fluoride of at least one rare earth element selected from rare earth elements comprising yttrium that belong in Group 3A;
(2) an oxyfluoride of the rare earth element;
(3) an oxide of the rare earth element;
(4) a composite oxide of the rare earth element and at least one or two or more metals selected from Al, Si, Zr and In; and
(5) a composite fluoride of the rare earth element and at least one or two or more metals selected from Al, Si, Zr and In,
the sprayed coating including at its surface a gray to black colored layer displaying a gray to black color having an L* value of 25 to 64, an a* value of −3.0 to +5.0, and a b* value of −6.0 to +8.0 when expressed by L*a*b* colorimetric system. This sprayed coating is thus obtained.

A treatment such that a surface layer of the coating is converted to a gray to black color with the specific chromaticity under the action of plasma light and reactive gas is applicable as the plasma exposure treatment. The frequency and power of plasma, the type, flow rate and pressure of reactive gas may be selected so as to attain the specific chromaticity. Other matters are the same as in the first embodiment. The spraying powder used in thermal spraying, as the same reason in the first embodiment, should have an oxygen content of preferably 0.01 to 13.5% by weight, more preferably 0.05 to 8% by weight although the oxygen content is not limited thereto.

### EXAMPLES

Examples and Comparative Examples are given below by way of illustration, however, Examples are not given by way of limitation for the present invention. In the followings, % is % by weight.

### Example 1

To 1 kg of ytterbium fluoride powder with an oxygen concentration of 3.4% and an average particle size of 40 μm, 1 L of 3% phenol diluted in ethanol was added. This was mixed for 5 minutes, dried, and roasted in nitrogen stream at 800° C. for 2 hours. The granulated powder was fired under a reduced pressure (below 1×10⁻² Torr) at 1,000° C. for 2 hours, yielding a spraying powder. This spraying powder displayed a black color of L*=42.3, a*=−0.30, and b*=−0.65, expressed by the L*a*b* colorimetric system, and had a carbon concentration of 1.3%. This spraying powder had an oxygen concentration of 2.9%.

The spraying powder was sprayed onto an aluminum alloy member to form a coating of about 200 μm thick by plasma spraying using argon and hydrogen gases. The sprayed coating was measured as a color of L*=45.2, a*=−0.53, and b*=−0.62, expressed by the L*a*b* colorimetric system, and had a carbon concentration of 1.1%. This sprayed coating had an oxygen concentration of 3.6%.

The spray coated member was set in a reactive ion plasma tester along with a resist-coated silicon wafer, and subjected to a plasma exposure test under conditions: frequency 13.56 MHz, plasma power 1,000 W, gas species CF₂+O₂ (20 vol %), flow rate 50 sccm, and gas pressure 50 mTorr. Upon removal from the tester, the sprayed coating showed no color change.

### Comparative Example 1

Ytterbium fluoride powder with an average particle size of 40 μm was sprayed onto an aluminum alloy member to form a coating of about 200 μm thick by plasma spraying using argon and hydrogen gases. The sprayed coating was measured as a color of L*=91.46, a*=−0.47, and b*=0.75, expressed by the L*a*b* colorimetric system, and had a carbon concentration of 0.003%.

The spray coated member was set in a reactive ion plasma tester along with a resist-coated silicon wafer, and subjected to a plasma exposure test under conditions: frequency 13.56 MHz, plasma power 1,000 W, gas species CF₄+O₂ (20 vol %), flow rate 50 sccm, and gas pressure 50 mTorr, as in Example 1. Upon removal from the tester, the sprayed coating partially showed brown and black discolored portions.

### Example 2

Yttrium fluoride powder with an oxygen concentration of 0.2% and an average particle size of 40 μm was immersed in a 30% aqueous solution of sucrose, which was stirred for 10 minutes, filtered and dried. The yttrium fluoride powder was fired in nitrogen stream at 800° C. for 2 hours and passed through a #100 screen, yielding a spraying powder. This spraying powder displayed a gray color of L*=72.23, a*=−0.02, and b*=3.12, expressed by the L*a*b* colorimetric system, and had a carbon concentration of 0.235%. This spraying powder had an oxygen concentration of 0.75%.

The spraying powder was sprayed onto an aluminum alloy member to form a coating of about 200 μm thick by plasma spraying using argon and hydrogen gases. The sprayed coating was measured as a color of L*=76.18, a*=0.04, and b*=3.77, expressed by the L*a*b* colorimetric system, and had a carbon concentration of 0.015%. This sprayed coating had an oxygen concentration of 1.1%.

The spray coated member was set in a reactive ion plasma tester along with a resist-coated silicon wafer, and subjected to a plasma exposure test under conditions: frequency 13.56 MHz, plasma power 1,000 W, gas species CF₄+O₂ (20 vol %), flow rate 50 sccm, and gas pressure 50 mTorr. Upon removal from the tester, the sprayed coating showed no color change.

### Example 3

To 150 g of yttrium oxide powder displaying white color with an average particle size of 1.1 μm and 850 g of yttrium fluoride powder with an average particle size of 3 μm, 4 L of 2% aqueous solution of acryl type binder was added. This was mixed into a slurry, which was granulated and dried through a spray dryer and passed through a #100 screen, yielding a spraying powder of yttrium fluoride powder with an average particle size of 36 μm. This spraying powder displayed a gray color of L*=88.48, a*=3.63, and b*=−2.85, expressed by the L*a*b* colorimetric system, and had a carbon concentration of 1.46% and an oxygen concentration of 3.37%. YF₃ and Y₂O₃ peaks were detected in X-ray diffraction measurement of the spraying powder.

The spraying powder was sprayed onto an aluminum alloy member to form a coating of about 200 μm thick by plasma spraying using argon and hydrogen gases. The sprayed coating was measured as a color of L*=43.18, a*=0.87, and b*=3.78, expressed by the L*a*b* colorimetric system, and had a carbon concentration of 0.068% and an oxygen concentration of 0.73%. Y₆O₅F₈, Y₅O₄F₇ and Y₂O₃ peaks were detected in X-ray diffraction measurement of the sprayed coating.

The spray coated member was set in a reactive ion plasma tester along with a resist-coated silicon wafer, and subjected to a plasma exposure test under conditions: frequency 13.56 MHz, plasma power 1,000 W, gas species CF₄+O₂ (20 vol %), flow rate 50 sccm, and gas pressure 50 mTorr. Upon removal from the tester, the sprayed coating showed no color change.

### Comparative Example 2

Yttrium oxide powder with an average particle size of 40 μm was sprayed onto an aluminum alloy member to form a coating of about 200 μm thick by plasma spraying using argon and hydrogen gases. The sprayed coating was measured as a color of L*=92.75, a*=−0.23, and b*=0.73, expressed by the L*a*b* colorimetric system, and had a carbon concentration of 0.002%.

The spray coated member was set in a reactive ion plasma tester along with a resist-coated silicon wafer, and subjected to a plasma exposure test under conditions: frequency 13.56 MHz, plasma power 1,000 W, gas species CF₄+O₂ (20 vol %), flow rate 50 sccm, and gas pressure 50 mTorr, as in Example 2. Upon removal from the tester, the sprayed coating partially showed brown and black discolored portions.

### Example 4

To 100 g of yttrium oxide powder displaying white color with an average particle size of 0.2 μm and 900 g of yttrium fluoride powder with an average particle size of 3 μm, 4 L of 1% aqueous solution of carboxymethyl cellulose (CMC) binder was added. This was mixed into a slurry, which was granulated and dried through a spray dryer, fired in nitrogen stream at 800° C. for 2 hours and passed through a #100 screen, yielding a spraying powder of yttrium fluoride powder with an average particle size of 37 μm. This spraying powder displayed a gray color of L*=58.46, a*=3.63, and b*=2.85, expressed by the L*a*b* colorimetric system, and had a carbon concentration of 1.34% and an oxygen concentration of 2.0%. YF₃ and Y₅O₄F₇ peaks were detected in X-ray diffraction measurement of the spraying powder.

The spraying powder was sprayed onto an aluminum alloy member to form a coating of about 200 μm thick by plasma spraying using argon and hydrogen gases. The sprayed coating was measured as a color of L*=37.78, a*=−0.06, and b*=5.78, expressed by the L*a*b* colorimetric system, and had a carbon concentration of 0.098% and an oxygen concentration of 3.26%. YF₃ and Y₅O₄F₇ peaks were detected in X-ray diffraction measurement of the sprayed coating.

The spray coated member was set in a reactive ion plasma tester along with a resist-coated silicon wafer, and subjected to a plasma exposure test under conditions: frequency 13.56 MHz, plasma power 1,000 W, gas species CF₄+O₂ (20 vol %), flow rate 50 sccm, and gas pressure 50 mTorr. Upon removal from the tester, the sprayed coating showed no color change.

### Example 5

To 100 g of aluminum oxide powder displaying white color with an average particle size of 3 μm and 900 g of yttrium fluoride powder with an average particle size of 3 μm, 4 L of 3% aqueous solution of acryl type binder was added. This was mixed into a slurry, which was granulated and dried through a spray dryer and passed through a #100 screen, yielding a spraying powder of yttrium fluoride powder having an oxygen concentration of 4.7% with an average particle size of 30 μm. This spraying powder displayed a white color of L*=90.24, a*=4.60, and b*=−5.55, expressed by the L*a*b* colorimetric system, and had a carbon concentration of 1.46%. YF₃ and Al₂O₃ peaks were detected in X-ray diffraction measurement of the spraying powder.

The spraying powder was sprayed onto an aluminum alloy member to form a coating of about 200 μm thick by plasma spraying using argon and hydrogen gases. The sprayed coating was measured as a color of L*=27.75, a*=2.96, and b*=0.64, expressed by the L*a*b* colorimetric system, and had a carbon concentration of 0.13% and an oxygen concentration of 4.9%. Y₆O₅F₈ and Y₃Al₅O₁₂ (YAG) peaks were detected in X-ray diffraction measurement of the sprayed coating.

The spray coated member was set in a reactive ion plasma tester along with a resist-coated silicon wafer, and subjected to a plasma exposure test under conditions: frequency 13.56 MHz, plasma power 1,000 W, gas species CF₄+O₂ (20 vol %), flow rate 50 sccm, and gas pressure 50 mTorr. Upon removal from the tester, the sprayed coating showed no color change.

### Example 6

To 50 g of yttrium oxide powder displaying white color with an average particle size of 0.2 μm, 50 g of aluminum oxide powder displaying white color with an average particle size of 3 μm and 900 g of yttrium fluoride powder with an average particle size of 3 μm, 4 L of 0.2% aqueous solution of CMC binder was added. This was mixed into a slurry, which was granulated and dried through a spray dryer, fired in nitrogen stream at 1,000° C. for 2 hours and passed through a #100 screen, yielding a spraying powder of yttrium fluoride powder having an oxygen concentration of 3.4% with an average particle size of 30 μm. This spraying powder displayed a white color of L*=89.52, a*=−0.07, and b*=1.92, expressed by the L*a*b* colorimetric system, and had a carbon concentration of 0.004%. Y₇O₆F₉+Y₃Al₅O₁₂ (YAG) peaks were detected in X-ray diffraction measurement of the spraying powder.

The spraying powder was sprayed onto an aluminum alloy member to form a coating of about 200 μm thick by plasma spraying using argon and hydrogen gases. The sprayed coating was measured as a color of L*=89.75, a*=−0.23, and b*=0.73, expressed by the L*a*b* colorimetric system, and had a carbon concentration of 0.009% and an oxygen concentration of 3.8%. Y₆O₅F₈ and Y₃Al₅O₁₂ (YAG) peaks were detected in X-ray diffraction measurement of the sprayed coating.

The spray coated member was set in a reactive ion plasma tester along with a resist-coated silicon wafer, and subjected to a plasma exposure test under conditions: frequency 13.56 MHz, plasma power 1,000 W, gas species CF₄+O₂ (20 vol %), flow rate 50 sccm, and gas pressure 50 mTorr. Upon removal from the tester, the sprayed coating showed no color change.

### Comparative Example 3

Yttrium fluoride powder with an oxygen content of 3% and an average particle size of 30 μm was sprayed onto an aluminum alloy member to form a coating of about 200 μm thick by plasma spraying using argon and hydrogen gases. The sprayed coating was measured as a color of L*=87.83, a*=−0.07, and b*=1.92, expressed by the L*a*b* colorimetric system, and had a carbon concentration of not more than 0.003%.

The spray coated member was set in a reactive ion plasma tester along with a resist-coated silicon wafer, and subjected to a plasma exposure test under conditions: frequency 13.56 MHz, plasma power 1,000 W, gas species CF₄+O₂ (20 vol %), flow rate 50 sccm, and gas pressure 50 mTorr, as in Example 3. Upon removal from the tester, the sprayed coating partially showed brown and black discolored portions.

### Example 7

To 1 kg of yttrium fluoride powder with an oxygen concentration of 12.8%, 1.5 L of 3% aqueous solution of polyvinyl alcohol (PVA) and 1.5 g of titanium chloride (TiCl₃) were added. This was mixed into a slurry, which was granulated and dried through a spray dryer, obtaining a granulated powder. The granulated powder was fired in argon gas stream at 1,000° C. for 1 hour and passed through a #200 screen, yielding a spraying powder. This spraying powder was measured as a black color of L*=38.21, a*=0.12, and b*=0.23, expressed by the L*a*b* colorimetric system, and had a titanium concentration of 680 ppm. This spraying powder had an oxygen concentration of 13.1%.

The spraying powder was sprayed onto an aluminum alloy member to form a coating of about 200 μm thick by plasma spraying using argon and hydrogen gases. The sprayed coating was measured as a color of L*=41.02, a*=−0.56, and b*=4.31, expressed by the L*a*b* colorimetric system, and had a titanium concentration of 670 ppm and an oxygen concentration of 13.5%.

The spray coated member was set in a reactive ion plasma tester along with a resist-coated silicon wafer, and subjected to a plasma exposure test under conditions: frequency 13.56 MHz, plasma power 1,000 W, gas species CF₄+O₂ (20 vol %), flow rate 50 sccm, and gas pressure 50 mTorr. Upon removal from the tester, the sprayed coating showed no color change.

### Example 8

To 1 kg of yttrium fluoride powder with an oxygen concentration of 2%, 1.5 L of 2% aqueous solution of polyvinyl alcohol (PVA) and 2.0 g of molybdenum chloride (MoCl₅) were added. This was mixed into a slurry, which was granulated and dried through a spray dryer, obtaining a granulated powder. The powder was fired in argon gas stream at 1,000° C. for 1 hour and passed through a #200 screen, yielding a spraying powder. This spraying powder was measured as a black color of L*=45.23, a*=−0.08, and b*=−0.21, expressed by the L*a*b* colorimetric system, and had a molybdenum concentration of 920 ppm and an oxygen concentration of 1.8%.

The spraying powder was sprayed onto an aluminum alloy member to form a coating of about 200 μm thick by plasma spraying using argon and hydrogen gases. The sprayed coating was measured as a color of L*=63.82, a*=−0.47, and b*=0.75, expressed by the L*a*b* colorimetric system, and had a molybdenum concentration of 890 ppm and an oxygen concentration of 2.5%.

The spray coated member was set in a reactive ion plasma tester along with a resist-coated silicon wafer, and subjected to a plasma exposure test under conditions: frequency 13.56 MHz, plasma power 1,000 W, gas species CF₄+O₂ (20 vol %), flow rate 50 sccm, and gas pressure 50 mTorr. Upon removal from the tester, the sprayed coating showed no color change.

### Examples 9, 10 and Comparative Examples 4, 5

A granulated powder as shown in Table 1 was prepared using gadolinium fluoride with an oxygen concentration of 0.48% and an average particle size of 27.8 μm and lanthanum fluoride with an oxygen concentration of 0.148% and an average particle size of 30.9 μm. The powder was fired under the conditions shown in Table 1 for 2 hours, yielding a spraying powder having a carbon content, oxygen content and chromaticity as shown in Table 1. The spraying powder was sprayed onto an aluminum alloy member as in Example 1 to form a sprayed coating having a carbon content, oxygen content and chromaticity as shown in Table 1. The spray coated member was subjected to the same plasma exposure test as in Example 1, after which the sprayed coating was examined for any change of chromaticity. The results are shown in Table 1.

TABLE 1

| | | | Comparative | | Comparative |
|---|---|---|---|---|---|
| | | Example 9 | Example 4 | Example 10 | Example 5 |
| Granulated | Material | GdF₃ | GdF₃ | LaF₃ | LaF₃ |
| powder | Particle size (μm) | 28.9 | 28.9 | 27.78 | 27.78 |
| | C content (wt %) | 0.06 | 0.06 | 0.088 | 0.088 |
| | O content (wt %) | 0.48 | 0.48 | 0.148 | 0.148 |
| | Appearance color | white | white | white | white |
| Firing conditions | Atmosphere | nitrogen | air | argon | air |
| | Temperature (° C.) | 800 | 800 | 800 | 800 |
| Spraying powder | C content (wt %) | 0.058 | 0.005 | 0.075 | <0.005 |
| | O content (wt %) | 0.483 | 0.467 | 0.152 | 0.143 |
| | Appearance color | deep gray | white | deep gray | white |
| | Chromaticity L* | 62.01 | 98.84 | 60.94 | 90.71 |
| | Chromaticity a* | +0.25 | +0.11 | +0.45 | −0.25 |
| | Chromaticity b* | +0.92 | +0.87 | +1.33 | −1.01 |
| Sprayed coating | C content (wt %) | 0.032 | <0.005 | 0.053 | <0.005 |
| | O content (wt %) | 1.0 | 0.550 | 0.203 | 0.257 |
| | Appearance color | deep gray | white | deep gray | white |
| | Chromaticity L* | 62.79 | 90.47 | 61.84 | 98.84 |
| | Chromaticity a* | +0.19 | −0.01 | +0.92 | +0.11 |
| | Chromaticity b* | +2.22 | −0.18 | +0.86 | +0.87 |
| Plasma exposure | Appearance color | deep gray | partially | deep gray | partially |
| test | | | discolored | | discolored |
| | | | (black areas) | | (black areas) |
| | Chromaticity L* | 60.94 | 59.22 | 58.21 | 52.3 |
| | Chromaticity a* | +0.45 | +0.88 | +1.52 | +1.46 |
| | Chromaticity b* | +1.33 | +0.24 | +4.35 | +6.86 |

As seen from Table 1, firing in an inert atmosphere (Examples 9 and 10) prevented the powder from lowering its carbon content, i.e., a carbon content of 0.01% or higher was maintained. In contrast, when the granulated powder was fired in air (Comparative Examples 4 and 5), the carbon content of the powder was reduced below 0.01% due to oxidation. A sprayed coating of the latter powder formed in white color.

### Experimental Examples

Seven species of coating powder varied in carbon contents were obtained, respectively, by using 100 g of yttrium oxide powder displaying white color with an average particle size of 0.2 μm, 900 g of yttrium fluoride powder with an average particle size of 3 μm, and CMC as a carbon source. Among these samples, Sample 6 was prepared as non-fired powder in accordance with the method of Example 3, and the others were prepared as fired powder in accordance with the method of Example 4. Next, a coating of about 200 μm thick which is shown in Table 2 was formed on an aluminum alloy member with using the spraying powder, respectively. Surface hardness (HV) and cross-section hardness (HV) were measured in each of the obtained sprayed coatings by the following method, and relation between the carbon content and the coating hardnesses were evaluated. The results are shown in Table 2 and shown graphically in FIG. 2

### Method for Measuring Hardness

From the obtained members, test pieces of 10 mm square size were prepared by cutting process. The surface of coating and cross-sectional surface were polished to mirror finish surface (Ra=0.1 μm), then hardnesses of the surface of coating and the cross-sectional surface were measured by Vickers hardness tester. The hardness was measured by Vickers hardness tester (AVK-C1, manufactured by Akashi Seisakusho, Ltd.) under loading of 300 gf and loading time of 10 second. The hardnesses of coating surface and cross-section surface were measured, respectively, at three points, and averages were evaluated.

TABLE 2

| | | Sample No. | | | | | | |
|---|---|---|---|---|---|---|---|---|
| | | 1 | 2 | 3 | 4 | 5 | 6 | 7 |
| Spraying powder | C content (wt %) | 0.004 | 0.007 | 0.033 | 0.079 | 0.134 | 0.626 | 0.242 |
| | Chromaticity L* | 90.47 | 90.71 | 71.57 | 59.08 | 58.46 | 88.46 | 51.94 |
| | Chromaticity a* | 0.11 | 0.1 | 4.39 | 3.67 | 0.26 | 3.63 | 0.45 |
| | Chromaticity b* | 0.87 | 1.01 | −2.10 | −2.81 | 0.70 | −2.85 | 1.33 |
| Sprayed coating | C content (wt %) | 0.004 | 0.01 | 0.02 | 0.048 | 0.098 | 0.139 | 0.2 |
| | Chromaticity L* | 88.92 | 87.83 | 81.2 | 57.39 | 37.78 | 37.39 | 37.47 |
| | Chromaticity a* | 4.43 | −0.07 | 4.22 | 4.22 | 3.09 | 3.22 | 2.98 |
| | Chromaticity b* | −5.63 | 1.92 | −2.41 | 2 | 1.08 | 1.89 | 0.65 |
| | Surface hardness | 324 | 434 | 385 | 475 | 467 | 342 | 125 |
| | (HV) | | | | | | | |
| | Cross-section | 391 | 438 | 333 | 406 | 419 | 422 | 199 |
| | hardness (HV) | | | | | | | |

As shown in Table 2 and FIG. 2, it is found that coating hardness reduces when a carbon content is more than 0.15% by weight, and good coating hardness over 300 HV attains when a carbon content is up to 0.15% by weight, particularly 0.1% by weight. Accordingly, a sprayed coating should have a carbon content of preferably up to 0.15% by weight, particularly 0.1% by weigh, when the sprayed coating is required high coating hardness.

### Examples 11-14

Each of ytterbium fluoride, yttrium fluoride, and gadolinium fluoride powders as shown in Table 3 was plasma sprayed onto an aluminum alloy member, as in Example 1, to form a sprayed coating as shown in Table 3. The sprayed coating was subjected to a plasma exposure under conditions: frequency 13.56 MHz, plasma power 1,000 W, gas species CF₄+O₂ (20 vol %), flow rate 50 sccm, and gas pressure 50 mTorr, obtaining the sprayed coating displaying chromaticity values as shown in Table 3.

TABLE 3

| | | | Example 11 | Example 12 | Example 13 | Example 14 |
|---|---|---|---|---|---|---|
| Spraying powder | | Material | YbF₃ | YF₃ | YF₃ | GdF₃ |
| | | C content (wt %) | 0.005 | 0.005 | 0.005 | 0.005 |
| | | O content (wt %) | 0.02 | 0.01 | 3 | 6 |
| Sprayed | Before plasma | Appearance color | white | white | white | white |
| coating | exposure test | Chromaticity L* | 90.47 | 87.77 | 87.82 | 90.71 |
| | | Chromaticity a* | −0.01 | −0.46 | −0.47 | −0.25 |
| | | Chromaticity b* | −0.18 | −0.27 | −0.23 | −1.01 |
| | After plasma | Appearance color | black | black | black | black |
| | exposure test | Chromaticity L* | 58.72 | 38.78 | 38.86 | 62.01 |
| | | Chromaticity a* | 0.26 | 1.45 | 1.5 | 0.25 |
| | | Chromaticity b* | 0.7 | 6.95 | 7.03 | 0.92 |

As seen from Table 3, when a rare earth fluoride sprayed coating normally looking white is subjected to plasma exposure treatment using plasma light and etching gas, the sprayed coating having uniform black color can be formed. When a member having this black sprayed coating is used as a plasma-resistant member in halogen gas, the coating experiences little or less partial discoloration. When the spray coated member is removed and cleaned, no excessive partial cleaning of the spray coated member is necessary, indicating that the spray coated member may surely realize its intrinsic long lifetime.

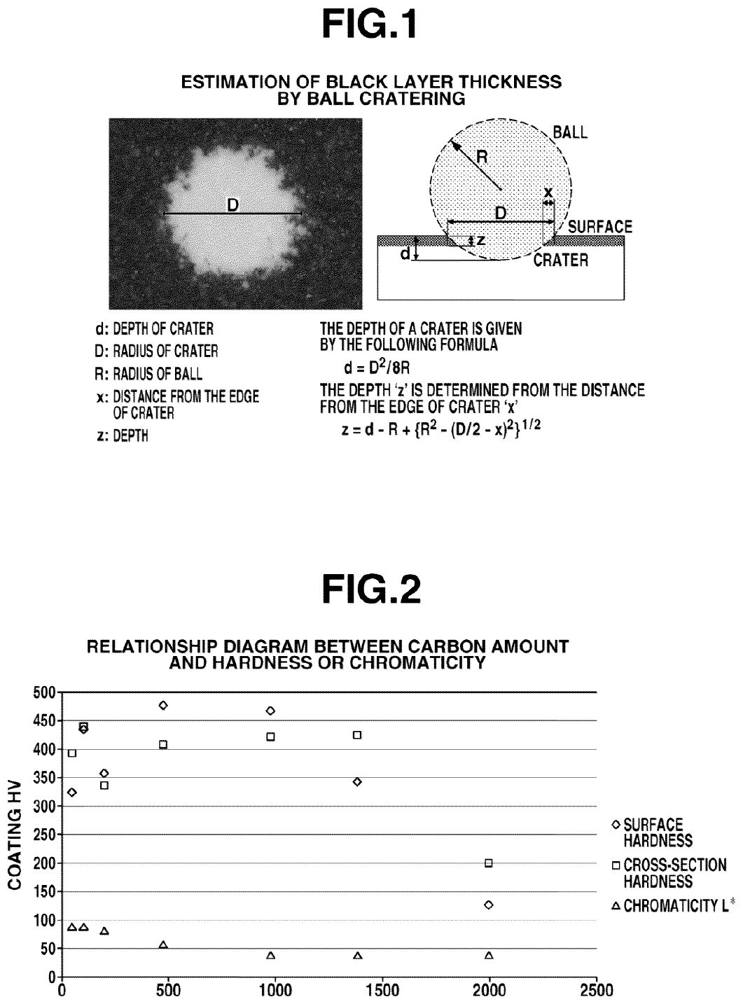

The black sprayed coating of Example 12 was measured for thickness by the ball cratering method, i.e., by grinding the spray coated member with a ball to define a crater having a diameter of 1,650 μm in its surface, and computing the thickness of black layer according to the formula shown in FIG. 1. The thickness was not more than 2 μm and estimated to be approximately 1,000 nm.

1. A spraying powder composed of the following (1) and/or (2), or the mixture of the following (1) and/or (2) and one or two or more selected from the following (3) to (6):
(1) a fluoride of at least one rare earth element selected from rare earth elements comprising yttrium that belong in Group 3A;
(2) an oxyfluoride of the rare earth element;
(3) an oxide of the rare earth element;
(4) a composite oxide of the rare earth element and at least one or two or more metals selected from Al, Si, Zr and In;
(5) a composite fluoride of the rare earth element and at least one or two or more metals selected from Al, Si, Zr and In; and
(6) an oxide of at least one or two or more metals selected from Al, Si, Zr and In,
wherein, the spraying powder contains 0.004 to 2% by weight of carbon or 1 to 1,000 ppm of titanium or molybdenum, and
the spraying powder displays a white color or gray to black color having an L* value of at least 25 and less than 91, an a* value of −3.0 to +5.0, and a b* value of −6.0 to +8.0, expressed by L*a*b* colorimetric system.

2. The spraying powder of claim 1 wherein the rare earth element is at least one selected from Y, Gd, Yb, and La.

3. The spraying powder of claim 1, having an oxygen content of 0.01 to 13.5% by weight.

4. The spraying powder of claim 1, being a fired spraying powder and having a carbon content of 0.004 to 0.15% by weight.

5. The spraying powder of claim 1, being an unfired spraying powder and having a carbon content of 0.004 to 1.5% by weight.
